(19) United States
(12) Patent Application Publication
(10) Pub. No.: US 2026/0323871 A1
(43) Pub. Date: Oct. 15, 2026

(54) MODULAR MANIFOLD ASSEMBLY

(71) Applicant: HEWLETT PACKARD ENTERPRISE DEVELOPMENT LP, Spring, TX (US)

(72) Inventors: Austin Edward Rodriguez, The Woodlands, TX (US); Steven Dale Webster, Montgomery, TX (US); Keith Allen Sauer, Spring, TX (US); David Allen Moore, Tomball, TX (US)

(21) Appl. No.: 19/177,856

(22) Filed: Apr. 14, 2025

(51) Int. Cl. H05K 7/20

(52) U.S. Cl. CPC H05K 7/20272; H05K 7/20236; H05K 7/20772

(57) ABSTRACT

An information processing system includes a system board having electronic components and a chassis supporting the system board, with the chassis having fan shroud attachment points configured to receive a fan shroud. The system further includes a modular manifold assembly. The modular manifold assembly includes a mounting structure having a base, a pair of side arms configured to couple to the chassis at the fan shroud attachment points, and a plurality of brackets coupled to the base. At least one manifold is configured to removably engage with the plurality of brackets.

Information processing systems, (e.g., servers) generate heat during operation and, if the heat is not dissipated or cooling is not provided, damage can occur to various components within the system. One way to provide cooling to a system is through the use of airflow through the system, such as by using fans disposed within the system, with airflow over components providing cooling. Another way to provide cooling to a system is through the use of liquid cooling, where coolant liquids flowing over components remove heat from the system.

### BRIEF DESCRIPTION OF THE DRAWINGS

The present disclosure can be understood from the following detailed description, either alone or together with the accompanying drawings. The drawings and related description of the figures are included to provide a further understanding of the present disclosure and are incorporated in and constitute a part of this specification. The drawings illustrate one or more nonlimiting aspects and implementations of the present teachings and together with the description explain certain principles and operation. In the drawings:

FIG. 1 is a block diagram of a system including a modular manifold assembly.

FIG. 2 is a top and rear perspective view of a modular manifold assembly.

FIG. 3 is a bottom and front perspective view of the modular manifold assembly of FIG. 2.

FIG. 4 is another bottom and front perspective view of the modular manifold assembly of FIG. 2.

FIG. 5 is a top view of the modular manifold assembly of FIG. 2.

FIG. 6 is a front view of the modular manifold assembly of FIG. 2.

FIG. 7 is a rear view of the modular manifold assembly of FIG. 2.

FIG. 8 is a side view of the modular manifold assembly of FIG. 2.

FIG. 9 is a perspective view of an information processing system including the modular manifold assembly of FIG. 2.

FIG. 10 is a method for adapting a system to include a modular manifold assembly.

### DETAILED DESCRIPTION

Information processing components, such as CPUs, are increasing in power and heat generation, which is making it increasingly difficult to efficiently cool the system via airflow. As heat generation increases, greater volumes of air must be moved through the system to achieve the same level of cooling. The increase in air volume through the system results in increased power consumption and increased noise. In addition, as the amount of air to be moved through the system increases, costs for the various components, such as fans and heat sinks, also increase.

One alternative method for cooling an information processing system is liquid cooling, in which liquid coolant is used to remove heat from a system. One form of liquid cooling is direct liquid cooling (DLC), in which liquid coolant flows through a system using tubes/pipes, and heat is extracted from heat generating components of the system into the liquid coolant via cold plates coupled to the components. DLC is often used in information processing systems having high component density, such as supercomputers or high-performance computing systems, where there are multiple components generating high amounts of heat. DLC is highly efficient at removing heat from a system, however, DLC has a high cost due to the addition of further components, such as cold plates and coolant pipes, to the system. Due to the complexity of many DLC cooled systems, these additional components are often customized for each particular system, meaning that many components cannot be easily reused.

Immersion cooling, on the other hand, involves submerging part or all of an information processing system in a tank of an electrically non-conductive liquid coolant, such as a dielectric liquid. This allows the liquid coolant to contact some or all of the information processing components, such that heat generated by the components can be discharged into the coolant. The heated coolant can then be circulated through a heat exchanger to remove the heat before being recirculated into the tank. Immersion cooling represents an efficient method of cooling a system without a corresponding increase in power or noise output, as may occur in an air-cooled system. Similarly, immersion cooling allows some of the benefits of direct liquid cooling, namely, the increase in heat able to be removed from the system without requiring a custom designed cooling system based on the particular information processing system. As such, the increase in accessibility and affordability of immersion cooling systems make immersion cooling an attractive option for system cooling.

However, existing information processing systems that were originally designed for air cooling may not be well optimized for immersion cooling. In general, an air-cooled system can be relatively easily converted to a state in which it can be used in an immersion cooling tank, for example by removing the air-cooling specific components, such as fans, heat sinks, and baffles, as well as by removing components incompatible with immersion, such as thermal pastes, stickers, or the like. This form of conversion may be referred to herein as a baseline conversion because it represents a minimal conversion to ready the system for immersion. While the aforementioned baseline conversion can relatively easily allow for an air-cooled system to be converted for use in the immersion cooling tank, the resulting system is not well optimized for immersion cooling and thus some of the benefits which may be possible with immersion cooling may not be fully realized. For example, it may be desirable to provide additional cooling to certain components, such as a CPU, beyond the cooling that occurs when the system which has been converted in the manner described above is immersed in an immersion tank.

To address these and other issues, examples disclosed herein relate to modular manifold assemblies which can be used as part of a modular immersion cooling adapter kit installed in an information processing system to optimize the system for immersion cooling. The modular manifold assembly may be coupled to a pump, which may also be part of the adapter kit. The pump may draw liquid coolant and supply a flow of the liquid coolant to the manifold. In some examples, the liquid coolant may be drawn from the pool in the immersion tank, while in other examples, the liquid coolant may be drawn from a tank associated with a heat exchanger via pipe routing between the tank and the pump. Once the liquid is drawn, the modular manifold assembly may then convert that flow of liquid into multiple output streams which the manifold directs towards electronic components of the system, such as the CPUs and memory modules. These output streams improve the rate of cooling of the electronic components by continually moving away the liquid surrounding the component which has already been heated by the component and replacing it with fresh cooler liquid.

These modular immersion cooling adapter kits, including the modular manifold assemblies disclosed herein, may be used as part of converting an information processing system originally designed for air cooling into an immersion ready state and may further optimize the system for immersion cooling beyond the baseline conversion. Optimized, in this context, means that the system is configured to provide superior cooling performance to one or more components, such as the CPU, beyond that which would be provided by the system without the modular adapter kits (i.e., beyond what would have been provided if only the baseline conversion were done). The adapter kits may, in some examples, be designed to leverage aspects of existing air-cooled system designs, thereby allowing for easy deployment of the modular adapters in the system during the conversion process. For example, portions of the adapter kits—including the modular manifold assembly, in some cases—may sit within spaces vacated by air cooling components removed during the conversion process and/or may attach and/or electrically connect to the system using the same mounting features and/or connectors previously used by now-removed air-cooling components. For instance, the modular manifold assembly may be configured to be installed in the space above the system board which would be occupied by a fan shroud in an air-cooled configuration of the system, i.e., the space above the CPU and memory modules, and in some examples the manifold may mount to the chassis using the same mounting features that would have been used by the fan shroud. This leveraging of air-cooling design features by the modular adapter kits makes it easier to convert an information processing system that was previously configured for air cooling to an immersion cooling configuration. Furthermore, even if a system is built from the beginning with immersion cooling in mind (rather than converting an air-cooled system), it may nevertheless be beneficial for the modular adapter kits to be designed to fit within spaces and utilize mounting feature normally used by air-cooling infrastructure because this may allow for certain parts—such as the chassis—to be shared in common between multiple different product lines. For example, an air-cooled system and an immersion cooled system could both share the same chassis design, which reduces development, manufacturing, and logistical costs.

The modular manifold assembly may comprise a mounting structure and a manifold which is supported by the mounting structure. The mounting structure is configured to be mounted to a chassis of an information processing system and extend across the width dimension thereof in a position above one or more electronic components, such as the CPUs and memory modules of the system board. The manifold may comprise a hollow body (e.g., tube) with an interior volume extending axially along the body's length, an inlet opening into the volume at one end of the body, and a plurality of outlets distributed along an axis parallel to the length of the body to eject liquid in a radial direction (a direction transverse to the axis).

In some examples, the mounting structure includes a base and one or more side arms extending from the base. Each side arm may include engagement features to engage with fasteners on opposite sides of the chassis. In some examples, the support structure may be coupled to the chassis at a location where a fan cage or fan shroud would be coupled in the system when the system was air cooled. Thus, the support structure is installable within a volume created by removal of air-cooling components, such as fans and fan shrouds.

The base of the mounting structure may include one or more pairs of brackets designed to receive and engage with the manifold. For a given pair of brackets, one bracket is disposed on one side of the base to support one end of the manifold and the other bracket is disposed on an opposite side of the base to support the other end of the manifold, with the manifold extending along a width dimension of the chassis. Each of the brackets may include an opening to receive an end of the manifold. In some examples, the opening of one of the brackets of a pair extends fully through the bracket such that a manifold can be slidingly engaged through the bracket during installation. The manifold may be located such that the output streams may be directed over one or more hot components within the information processing system. In some examples, the manifolds may engage with detent features on the brackets to aid in positioning the manifold and particularly fluid outlets of the manifold. More particularly, engagement of the manifold with the detent features may aid in positioning the outlets with respect to the components to be cooled.

In some examples, multiple pairs of brackets are provided. This can allow for a single manifold to be installed in a variety of locations on the base, or it can allow for multiple manifolds to be simultaneously installed. This contributes to the modular nature of the manifold assembly, allowing it to be easily adapted to a variety of different system configurations and needs. For example, in some immersion cooling systems, a bulk liquid flow direction through the chassis may be from a front to a rear, and which case the manifold assembly can be configured with the manifold on a front side of the CPUs to allow for the output streams thereof to be directed in a generally rearward direction, coincident with the bulk liquid flow direction. In another immersion cooling system in which the bulk liquid flow direction through the chassis is from a rear to a front, the manifold assembly can instead be configured with the manifold on a rear side of the CPUs to allow for the output streams thereof to be directed in a generally forward direction, coincident with the bulk liquid flow direction. In examples in which multiple manifolds are included, each manifold may have an identical structure as the other, allowing for a single part number to be used for both, which reduces manufacturing and logistics costs.

The modular manifold assembly may further have a distribution pipe with one or more outlets coupled to the brackets on one side of the mounting structure. The outlets of the distribution pipe may be coupled to a side of the bracket(s) which is opposite the side to which the manifolds may couple. A given outlet of the distribution pipe may be fluidically coupled with the inlet of a manifold when the manifold is installed within the bracket to which the given outlet is coupled, allowing coolant to flow through the distribution pipe, into the manifold, and out the outlet nozzles of the manifold. Thus, the brackets not only physically support the distribution pipe and the manifold, but they may also form part of the fluid flow path connecting the two together.

In some examples, the distribution pipe may have two fluid inlets separated by a tube body, allowing for flexibility in the location of a pump which supplies liquid to the distribution pipe. In some examples, if an outlet of the distribution pipe is not being used, then it may be blocked with a plug. In other examples, valves may be used to selectively block or unblock outlets of the distribution pipe. A bidirectional valve on the inlet pipe may be movable to allow adjustment of fluid flow direction within the inlet pipe; that is, the bidirectional valve may allow one of the two fluid inlets of the inlet pipe to be selectively sealed. This may allow the information processing system to be immersed within the liquid coolant in multiple orientations, adding modularity to the manifold assembly.

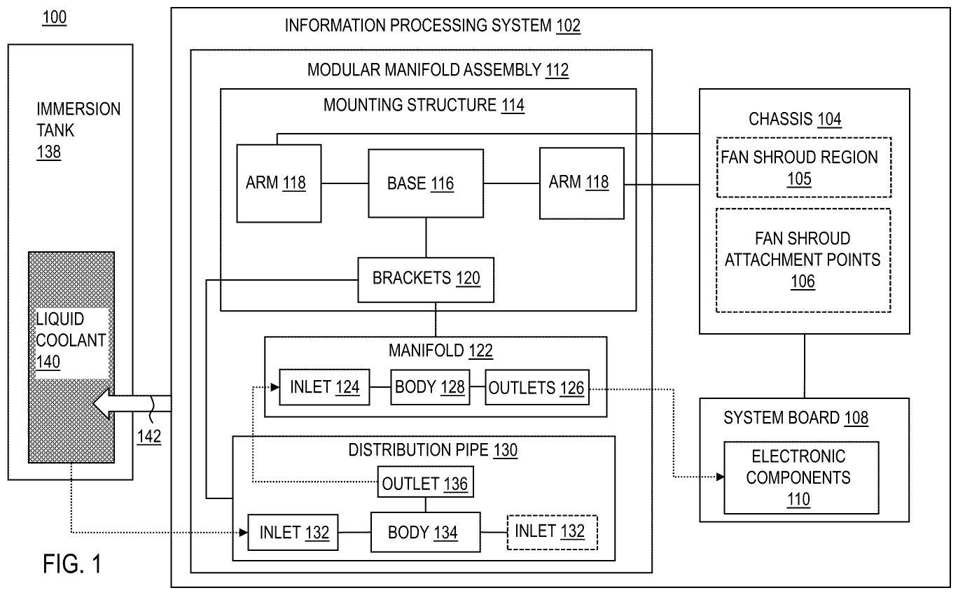

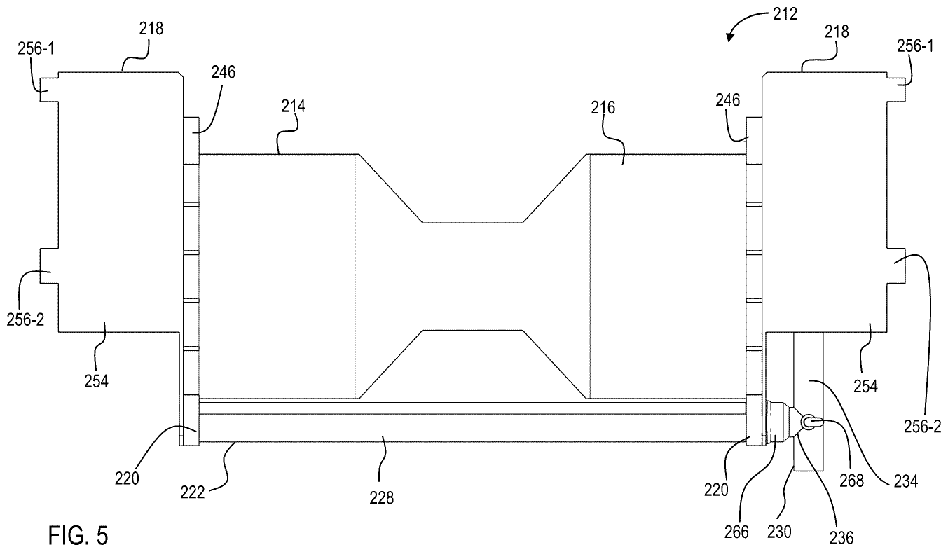

These and other examples will be described in greater detail below in relation to FIGS. 1-10.

FIG. 1 illustrates an example system 100. FIG. 1 is schematic in nature, and it should be understood that FIG. 1 is not intended to illustrate specific shapes, dimensions, positional relationships, or other structural details accurately or to scale, unless otherwise noted herein. Implementations of information processing system 100 may have different numbers and arrangements of the illustrated components. In addition, components illustrated in FIG. 1 may be omitted from some examples disclosed herein, and components which are not illustrated in FIG. 1 may also be included in some examples disclosed herein. In FIG. 1, physical connections (e.g. physical attachment and/or support) between components are indicated conceptually by solid lines extending between the components. Certain positional relationships are indicated by thick, white-filled arrows. Motion of coolant is indicated by dotted-line arrows.

System 100 is a system for immersion cooling information processing devices, such as servers, networking devices, or the like. System 100 includes an information processing system 102 and an immersion tank 138. The immersion tank 138 contains a pool of liquid coolant 140 and is configured to receive multiple information processing systems immersed in that coolant 140 to provide immersion cooling thereto, as will be explained in greater detail below.

Information processing system 102 may be a server, a networking device (e.g., switch, router, etc.), or other device with information processing components. Information processing system 102 may include a chassis 104, a system board 108, and a modular manifold assembly 112.

Chassis 104 may include structural components to support and/or house other components of the system 102. The chassis 104 may, for example, include a housing or enclosure comprising walls or panels, such as a base, side walls, a cover coupled together to define an interior volume in which other components of the system are housed. The chassis may also include other support structures, which may be disposed in or form integral parts of the aforementioned housing, such as drive cages, power supply unit cages, etc. In lieu of forming a housing, chassis 104 may alternatively include a tray or other support structure which supports, but does not necessarily fully enclose, the components of the system.

In some examples, system 102 is compatible with both air-cooling and immersion cooling, meaning that the system 102 is switchable between an air-cooled configuration and an immersion cooled configuration. In such examples, chassis 104 may further include a fan shroud region 105 and fan shroud attachment points 106 (these are illustrated in FIG. 1 in dotted lines to indicate that they are not necessarily present in all examples of the system 102). Fan shroud region 105 is a region in the chassis 104 configured to receive a fan shroud in the air-cooled configuration. A fan shroud is a device comprising airflow control structures (e.g., baffles, apertures, etc.) which facilitate desired airflow patterns through certain regions of an information processing by selectively blocking, allowing, or redirecting airflows. In particular, the fan shroud is commonly positioned in the space above the CPU(s) and memory modules (i.e., between these components and the top cover of the chassis 104) and configured to increase the amount of air that flows through the CPU heatsinks and the memory modules. Thus, in some examples, the fan shroud region 105 corresponds to this space above the CPUs and memory modules. Fan shroud attachment points 106 comprise attachment features configured to attach the fan shroud to the chassis 104. In some examples, fan shroud attachment points 106 may be disposed in or on side walls of chassis 104 and/or a base of the chassis 104. For example, the side walls may include slots which are configured to receive laterally protruding tabs of the fan shroud. When the system 102 is deployed in an immersion cooled configuration, the fans, fan cage, and fan shroud may be removed. Therefore, in the immersion cooled configuration, if any fan shroud region 105 and fan shroud attachment points 106 are included in the system 102, they are not used by the fan shroud and instead may be used, in some examples, by the modular manifold assembly 112 described below.

A system board 108 may be supported by chassis 104. The system board 108 may be a motherboard that includes electronic components 110 coupled thereto. Electronic components 110 include at least some information processing components, such as a central processing unit (CPU), a memory, or the like, as well as other passive or active electrical components (not illustrated), but examples are not so limited, and any system board may be used.

A modular manifold assembly 112 may be coupled to chassis 104 at the fan shroud attachment points 106. Modular manifold assembly 112 may include a mounting structure 114, a manifold 122, and a distribution pipe 130, which together allow information processing system 102 to be cooled via direct liquid cooling.

Mounting structure 114 is configured to be coupled to the chassis 104 and to support the other components of the modular manifold assembly 112 relative to the chassis 104 when the modular manifold assembly 112 is installed in the system 102. The mounting structure 114 may include a base 116, which may be generally planar. The base 116 is configured such that, when modular manifold assembly 112 is coupled to chassis 104, base 116 is substantially parallel to system board 108 and extends across a width dimension of the chassis 104. In some examples, base 116 is configured to be positioned in the fan shroud region 105.

The mounting structure 114 may further comprise, in some examples, one or more side arms 118 that are coupled to base 116, with the side arms 118 being configured to engage with the chassis 118 and thereby couple the mounting structure 114 to the chassis 118. In some examples, side arms 118 may be disposed opposite one another, with base 116 extending between arms 118 and side arms 118 protruding laterally from the base 116 in opposite directions from one another, i.e., one side arm 118 extends from one end portion of base 116 towards one side wall of chassis 104 and the other side arm 118 extends from another end portion of the base 116 towards the other side wall of the chassis 104. More particularly, in some examples side arms 118 may include attachment features to couple to fan shroud attachment points 106, allowing modular manifold assembly 112 to be coupled to chassis 104. In some examples, the fan shroud attachment points 106 include two sets of fan shroud attachment points 106 disposed in two opposite side walls of the chassis 104, and the side arms 118 may respectively engage with these sets of fan shroud attachment points 106, i.e., one side arm 118 engages one set of fan shroud attachment points in one side wall and the other side arm 118 engages the other set of fan shroud attachment points in the other side wall.

The mounting structure 114 further comprises a plurality of brackets 120 which are coupled to base 116. The brackets 120 are configured to engage with manifold 122 and distribution pipe 130, both described below, to couple those parts to the mounting structure 114. In some examples, brackets 120 may be disposed in pairs, wherein each pair of brackets 120 is configured to hold the manifold 122 in a corresponding installation position relative to base 116. For a given pair of the brackets 120, one bracket 120 may be disposed on one side of the base 114 to support one end of the manifold 122 and the other bracket 120 may disposed on an opposite side of the base 114 to support the other end of the manifold 122, such that the manifold 112 extends along a width dimension of the chassis 104. Each of the brackets 120 may include a hole (e.g., bore) to receive an end of the manifold 122. In some examples, the hole of one of the brackets 120 of a pair extends fully through the bracket 120 such that a manifold 122 can be slidingly engaged through the bracket 120 during installation.

In some examples, base 116 may include multiple pairs of brackets 120, with each pair of brackets 120 configured to hold a manifold 122. For example, one pair of brackets 120 may be located adjacent a front side of the base 114 (e.g., one bracket 120 of the pair near a front-left portion of the base 114 and the other bracket 120 of the pair on the front-right portion of the base 114) while another pair of brackets 120 may be located adjacent a rear side of the base 114 (e.g., one bracket 120 of the pair near the rear-left portion of the base 114 and the other bracket 120 of the pair near the rear-right portion of the base 114). The number of pairs of brackets 120 is limited only by the space constraints of the system, and in some examples can include one, two, three, four, or any number more of pairs of bracket 120. Providing multiple pairs of the brackets 120 can allow for a single manifold 122 to be installed in a variety of locations on the base 114, or it can allow for multiple manifolds 122 to be simultaneously installed. This contributes to the modular nature of the manifold assembly 112, allowing it to be easily adapted to a variety of different system configurations and needs. In addition, while the manifold 122 is illustrated and described as being held by a pair of brackets 120, examples are not so limited, and the manifold 122 may be held by any number of brackets 120.

The manifold assembly 112 further includes one or more manifolds 122, which may be coupled to mounting structure 114. As used herein, a manifold refers to a structure that receives a liquid input and distributes the input to multiple outputs. Manifold 122 comprises a manifold body 128, an inlet 124, and multiple outlets 126. Manifold body 128 may be hollow, defining an internal volume through which a coolant liquid can flow. The internal volume in manifold body 128 may be fluidically coupled to a plurality of fluid outlets 126. The fluid outlets 126 comprise holes through an outer wall of the manifold body 128 which fluidically connect the internal volume with the environment outside the manifold body 128. In some examples, the fluid outlets 126 comprise just the hole. In other examples, the fluid outlets 126 may comprise additional structures, such as nozzles, which are fluidically coupled with the internal volume via the holes. Fluid outlets 126 may be integrally formed within manifold body 128; however, examples are not so limited and fluid outlets 126 may be separately coupleable to manifold body 128.

Manifold body 128 may further be coupled to a fluid inlet 124. The inlet 124 comprises a hole through an outer wall of the manifold body 128 which fluidically connects the internal volume with the environment outside the manifold body 128. In some examples, fluid inlet 124 may include an intake fluid coupling (e.g., a friction-fit fluid coupling, a hose barb, a threaded fitting, a compression fitting, etc.) which can couple with a tube or pipe, although examples are not so limited (more specifically, the inlet 124 may comprise one half of such a fluid coupling in cases where the fluid coupling comprises two mating halves).

Fluid inlet 124 may be fluidically coupled with fluid outlets 126 via the internal volume of the manifold body 128, such that liquid coolant 140 is able to flow into the internal volume of manifold body 128 via the fluid inlet 124 and then through the manifold body 128 before exiting via the fluid outlets 126 as multiple output streams of coolant 140. A pump (not illustrated) may supply this flow of liquid coolant 140. The outlets 128 may be arranged such that, when the modular adapter 112 is installed in the chassis 104, the output streams are directed towards electronic components 110, such as the CPU and/or memory.

Manifold body 128 may be received in and supported by brackets 120, with one end of the body 128 engaged with one bracket 120 of a pair and the other end of the body 128 engaged with the other bracket 120 of a pair. When so installed, a longitudinal dimension of the manifold body 128 may be substantially parallel to a length of base 116, which is parallel to the width dimension of the chassis 104 when the modular manifold assembly 112 is installed therein. In some examples, the outlets 126 may be distributed along the longitudinal dimension of the manifold body 128 to allow for the output streams of liquid coolant to be distributed across the width of the chassis 104. In some examples, the manifold body 128 may have the shape of a tube or pipe (i.e., a hollow cylindrical shell), such that the longitudinal dimension of the manifold body 128 is parallel to a central axis of tube-like manifold body 128. In some examples, the inlet 124 comprises an opening in an end of the tube-like manifold body 128.

A distribution pipe 130 may be physically coupled with mounting structure 114 and fluidically coupled to the manifold 122. Distribution pipe 130 comprises a distribution pipe body 134, which has a hollow internal volume. The distribution pipe 130 also has at least one inlet 132 fluidically coupled to the hollow internal volume. In some examples, the distribution pipe may have multiple (e.g., a pair) inlets 132 arranged at different locations along the distribution pipe body 134. For example, in some instances two inlets 132 may be disposed at opposite ends of distribution pipe body 134, such that fluid is able to enter the internal volume of the distribution pipe 130 at either end and flow through the distribution pipe body 134. In some examples in which there are multiple inlets 132, one inlet may be selected for receiving input fluid (e.g., from a pump via another liquid conduit coupled to the selected inlet 132) and the other inlet 132 may be closed with a plug, cap, or valve. In other cases, multiple inlets 132 may be simultaneously receive input fluid from different liquid conduits coupled thereto.

Distribution pipe 130 may further contain at least one outlet 136 fluidically coupled with the internal volume. Outlet 136 may include a hole extending through a wall of the distribution pipe body 134, as well as a fluid coupling (or portion thereof), in some examples, which is fluidically coupled with the hole. The outlet 136 is configured to be fluidically coupled with the inlet 124 of manifold 122. Thus, distribution pipe 130 may be fluidically coupled to manifold 122 such that fluid is able to flow into the distribution pipe 130 via at least one of the fluid inlets 132 and through the distribution pipe body 134 before exiting at outlet 136 and flowing into and through manifold 122.

In some examples, the outlet 136 of distribution pipe 130 is directly physically coupled and fluidically coupled with the inlet 124 of the manifold 122. For example, the inlet 124 and outlet 136 may form two halves of a fluid coupling which mate together. In such examples, inlet 124 and the outlet 136 may both be physically coupled to the mounting structure 114 by one of the brackets 120, but the bracket 120 does not necessarily participate in the fluid coupling therebetween.

In other examples, the bracket 120 may both physically couple the distribution pipe 130 and manifold 122 to the mounting structure 114 and also participate in the fluidic coupling of the distribution pipe 130 with manifold 122. In other words, the bracket may be (or act as) a fluid coupling which couples the inlet 124 to the outlet 136. For example, the bracket 120 may include a bore extending through the bracket 120 with a first opening at a first end of the bracket 120 and a second opening at a second end of the bracket 120, and the manifold 122 may be coupled to the first end of the bracket 120 in or over the first opening, while the distribution pipe 130 may be coupled to the second end of the bracket 120 in or over the second opening, such that the bore forms at least part of the fluid path fluidically connecting the outlet 136 of the pipe 130 to the inlet 124 of the manifold 122. In some examples, the inlet 124 may be inserted through the first opening into the bore of the bracket 120, while in other examples, first end of the bracket 120 may be inserted into the inlet 124. In some examples, the outlet 136 may be inserted through the second opening into the bore of the bracket 120, while in other examples, the second end of the bracket may be inserted into the outlet 136. In each of these examples, the manifold 122 is fluidically connected to the distribution pipe 130 via the bore of the bracket 120, the inlet 124, and the outlet 136.

In some examples, the distribution pipe 130 includes multiple outlets 136. In some examples, there may be one outlet 136 per pair of brackets 120, with each outlet 136 being coupled with a bracket 120 of a corresponding pair. This can allow the distribution pipe 130 to supply liquid to a manifold 122 coupled to any one of the pairs of brackets 120, further increasing flexibility of system. For example, if only one manifold 122 is being used, then the outlet 136 coupled to that manifold 122 may be left open and the other outlets 136 may be closed, for example by a plug, cover, or valve. Or, as another example, if multiple manifolds 122 are being used, then the outlets 136 coupled to those manifold 122 may be left open, allowing distribution pipe to simultaneously supply liquid to those manifolds 122.

As noted above, in some examples where multiple inlet 132 and/or multiple outlets 136 are provided, valves may be used to selectively close the inlets 132 and/or outlets 136. In some of these examples, these valves may be provided in distribution pipe body 130. In other examples, these valves may be provided in, or as part of, the inlets 132 and/or outlets 136. In some examples, the valves may be separate parts which are coupled to distribution pipe body 130, inlets 132, and/or outlets. In some examples, the valves may be part of or coupled to the brackets 120. In some examples, a valve, such as a three-way valve, may be shared by an inlet 132 and an outlet 136, meaning the same single valve may control the flow of liquid through both that inlet 132 and that outlet 136.

System 100 may further include an immersion tank 138 including liquid coolant 140 held in a liquid-holding portion of the tank 138 to create a pool of liquid coolant 140. The liquid-holding portion of the tank 138 may be configured to receive information processing system 102 such that information processing system 102 is immersed in the pool of liquid coolant 140. As used herein, “immersed” means that at least one electronic component 110 on the system board 108 is submerged in the liquid coolant 140. In some examples, the entirety of each information processing system 102 may be fully submerged. In other examples, a portion of a system 102, such as a support bracket which supports the system, may protrude out of the liquid coolant 140. The immersion of system 102 in the liquid coolant 140 is shown by arrow 142.

The coolant 140 may be an electrically non-conducting material that is liquid at room temperatures, such as dielectric fluid. Immersion of information processing system 102 into liquid coolant 140 allows heat generated by electronic components 110 to be removed from the information processing system 102. More particularly, heat from components of the system is transferred into the circulating coolant 140.The heat is then released externally from the system. In some examples, the coolant 140 may be a single-phase coolant, meaning it is engineered to absorb heat and circulate it through the immersion tank 130. This circulation may include transferring the absorbed heat to a heat exchanger (not shown in FIG. 1) before being circulated back through the immersion tank 138, thus allowing liquid coolant 140 to be continually moved over the information processing system 102. In other examples, the coolant 140 is a two-phase coolant, meaning it is engineered to transport heat by changing between liquid and vapor (gas) phases during operation of the device. In such examples, the coolant 140 has a boiling point which is near a desired operating temperature of the electronic components 110, which means that the electronic components 110 can bring the coolant 140 to boiling during operation. This boiling absorbs heat from the components and allows the heat to be dissipated via interaction of coolant 140, in vapor form, with a heat sink or other heat dissipating structures (not shown).

When information processing system 102 is immersed in liquid coolant 140, distribution pipe 130 may be configured to move liquid coolant 140. More particularly, distribution pipe 130 may move liquid coolant 140 from the pool in the immersion tank 130 to fluid inlet 132. Liquid coolant 140 may then move through distribution pipe body 134 and exit at outlet 136. Because distribution pipe 130 is fluidically coupled with manifold 122, upon exiting outlet 136, liquid coolant 140 then flows through inlet 124 of manifold 122. Liquid coolant 140 flows through manifold body 128 before flowing through outlets 126 of manifold 122. In some examples, fluid outlets 126 may direct liquid coolant 140 over electronic components 110 on system board 108. More particularly, fluid outlets 126 may be oriented to flow over selected electronic components 110. For example, fluid outlets 126 may be positioned to allow liquid coolant 140 to flow over high-temperature components, such as a processing unit or a memory, thus allowing additional liquid coolant 140 to be moved over components, increasing the cooling of these components.

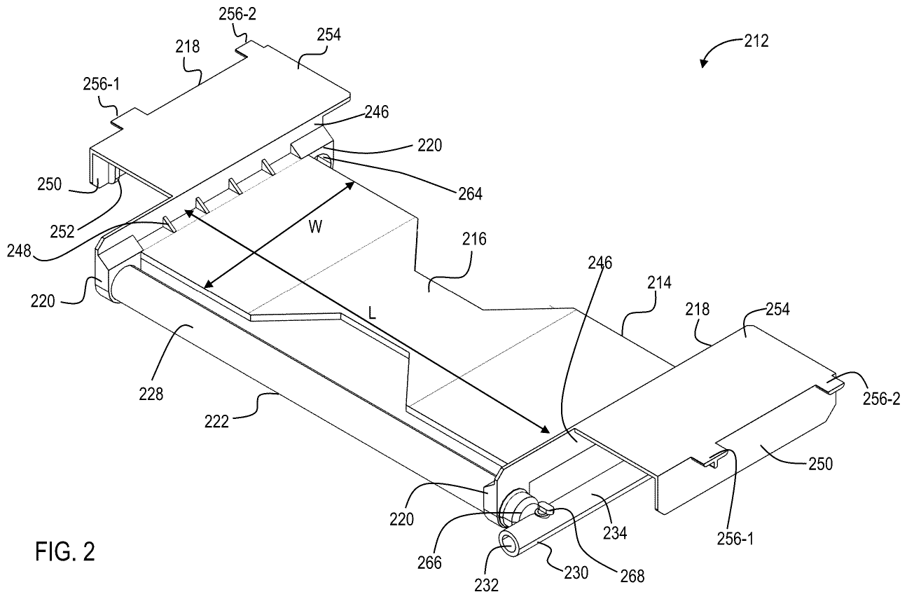

Turning to FIGS. 2-8, an example modular manifold assembly 212 is shown. Modular manifold assembly 212 may be one implementation of an example modular manifold assembly 112, shown in and described with respect to FIG. 1, and may be used in a system such as system 100, described with respect to FIG. 1. Modular manifold assembly 212 thus comprises components which correspond to (i.e., are implementation examples of) components of the modular manifold assembly 112, and the correspondence between such components is indicated herein by the components having references numbers with the same last two digits, such as 112 and 212. Aspects of the modular manifold assembly 112 and its components described above may also be applicable to the modular manifold assembly 212 and its corresponding components, but the modular manifold assembly 112 and its components are not limited to the modular manifold assembly 212 and its components, which are just one example of how the modular manifold assembly 112 may be implemented. In some instances, aspects of the modular manifold assembly 112 already described above, which are also applicable to the modular manifold assembly 212, are not described below to avoid duplicative description. Modular manifold assembly 212 includes a mounting structure 214, a manifold 222, and a distribution pipe 230.

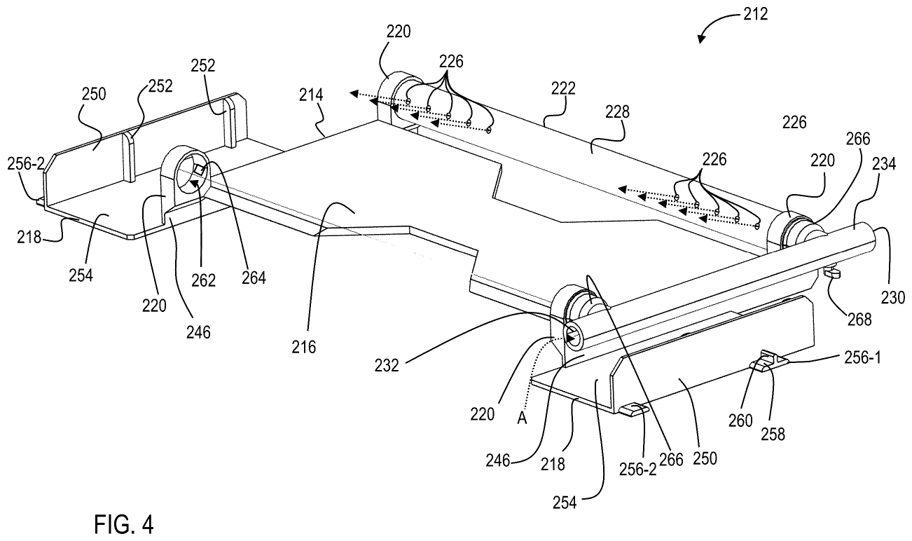

Mounting structure 214 includes a base 216. Base 216 is generally planar. One or more side arms 218 may extend from base 216. In some examples, a pair of side arms 218 extend from base 216, with base 216 separating side arms 218. Each side arm 218 includes a first vertical portion 246 adjacent to base 216 and a second vertical portion 250 parallel to and spaced apart from first vertical portion 246. Supports 248 extend along the first vertical portion 246 between base 216 and first vertical portion 246 to provide additional structure and support for first vertical portion 246. Similarly, as shown particularly in FIG. 4, supports 252 extend along an inner surface of the second vertical portion 250. Supports 252 provide structure and support for second vertical portion 250.

First vertical portion 246 and second vertical portion 250 are connected by a top portion 254 extending between the first vertical portion 246 and the second vertical portion 250. Top portion 254 is substantially planar and generally parallel to base 216. A plurality of attachment features 256 extend outwardly from top portion 254. Attachment features 256 may be integrally formed as part of arm 218 or may be formed separately and subsequently attached. These attachment features 256 may include a first type of attachment feature 256-1 and a second type of attachment feature 256-2 (collectively, attachment features 256) are configured to mate with fan shroud attachment points, allowing modular adapter 212 to be installed in a chassis in the volume otherwise occupied by the fan shroud.

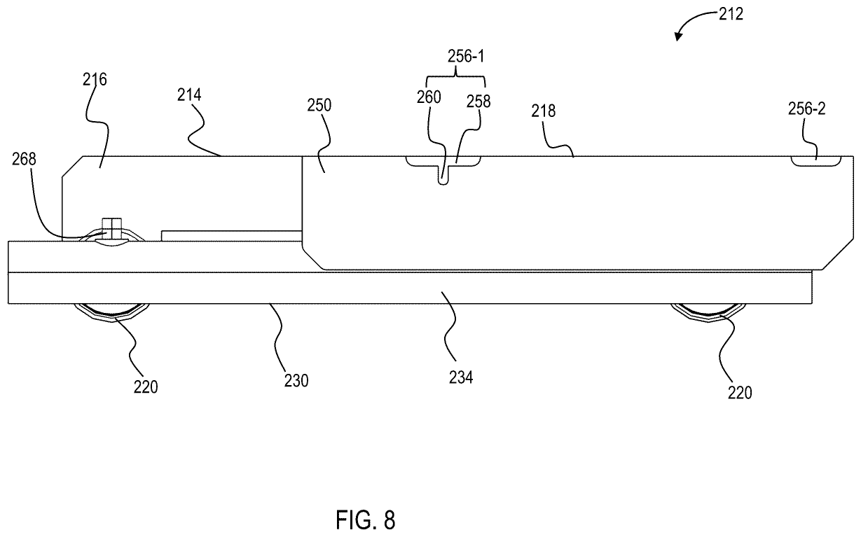

More particularly, as shown particularly in FIG. 8, attachment feature 256-1 includes a horizontal portion 258 and a vertical portion 260 joined together perpendicularly to form a T-shaped profile, which together form the attachment feature 256-1. Each of the horizontal portion 258 and the vertical portion 260 are configured to engage with complementary attachment features in the chassis. For example, complementary attachment features may include a horizontal shelf and a vertical slot extending down through the shelf such that the vertical portion 260 can slidingly engage with the vertical slot while the horizontal portion rests on the shelf. The shelf may be formed, for example, from a bottom rim of a horizontal slot cut into a chassis side wall, such that the horizontal slot and vertical slot together form an opening in the side wall which is similar to the T-shaped profile of the attachment feature 256-1. In some examples, the attachment feature 256-1 is retained in engagement with the chassis by gravity and/or by a cover of the chassis. In other examples, the attachment feature 256-1 is further secured to the chassis 204 by, e.g., a snap fit or a friction fit, to retain the mounting structure 214 in an installed position with respect to the chassis. Attachment feature 256-2, meanwhile, is a horizontal tab configured to engage with a second complementary attachment features in the chassis, such as another horizontal shelf similar to the one described above. In some examples, the attachment feature 256-2 is retained in engagement with the chassis by gravity and/or by a cover of the chassis. In other examples, attachment feature 256-2 is configured to further be secured to the chassis by, e.g., a snap fit or a friction fit; however, examples are not so limited.

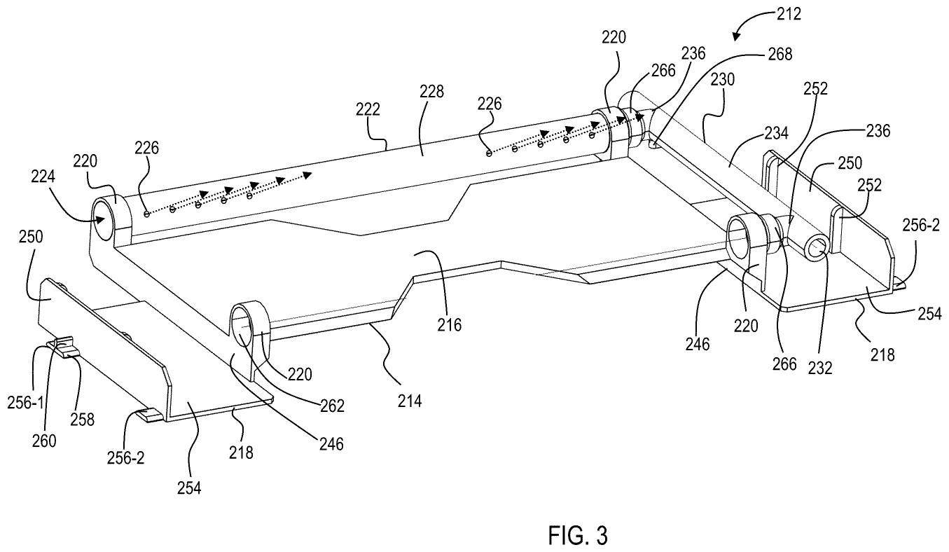

Mounting structure 214 further includes brackets 220 coupled to base 216. In some examples, brackets 220 are integrally formed with base 216 of mounting structure 214. As shown in FIGS. 3 and 4, brackets 220 are disposed adjacent to first vertical portion 246 of side arms 218. As further shown, brackets 220 may be disposed in pairs, with one bracket 220 disposed adjacent to one side arm 218 and the other bracket 220 disposed adjacent to the opposite side arm 218, with the pair of brackets 220 being separated by the length L of base 216. A first pair of brackets 220 is disposed at one edge of base 216 and a second pair of brackets 220 is disposed parallel to and offset from the first pair of brackets 220 by a width W of the base 216.

Brackets 220 include an opening 262 configured to receive a component, such as manifold 222. Each pair of brackets 220 is configured to receive a component, such that the component may be installed on either side of the manifold body 216. This affords the modular manifold assembly 212 flexibility, such that the modular manifold assembly 212 can be used in multiple orientations. The particular side of the mounting structure 214 to which a component is coupled may be determined by system considerations, such as location of electronic components on the system board to be cooled and location of attachment features on the chassis.

As shown in FIG. 4, brackets 220 include a detent feature 264 on an interior portion of bracket 220. While only one detent feature 264 is shown in FIG. 4, it should be understood that each bracket 220 has a detent feature 264. Detent feature 264 aids in positioning manifold 222 received in bracket 220. The detent feature 264 is configured to engage with a corresponding detent feature on the manifold 222 when the manifold 222 is installed in a correct position and/or orientation. In some examples, the detent feature 264 may comprise a protrusion while the corresponding detect feature comprises a recess, while in other examples, the detent feature 264 may comprise a recess while the corresponding detect feature comprises a protrusion. The engagement of the detent feature 264 with the corresponding detent feature of the manifold 222 may give a tactile feedback to an assembler indicating that the manifold 222 is correctly positioned and/or orientated. In some examples, the detent feature 264 may also lock the installed manifold 222 into this position and/or orientation with respect to brackets 220 by resisting movement of the bracket 220 out of this position or orientation.

In some examples, the predetermined orientation at which the detent 264 holds the manifold 222 may be configured to cause the outlets 226 to face towards the electronic components that the manifold 222 is intended to cool. In other words, the detents 264 may help ensure the manifolds 222 are properly positioned to expel the streams towards the intended electronic components. In some examples, the detents 264 of different pairs of brackets 220 may be arranged to hold the manifold 222 in mutually different orientations to account for the different locations of the brackets 220. For example, if one pair of bracket 220 holds the manifold 220 at a position slightly rearward of a CPU, its detent 264 may be configured to orient the manifold 222 with the outlets 226 facing at an angle down and forward so that the outlet streams flow towards the CPU, whereas if a different pair of brackets 220 holds the manifold 220 at a position slightly forward of the CPU, its detent 264 may be configured to orient the manifold 220 with the outlets 226 facing at an angle down and rearward so that the outlet streams flow towards the CPU.

Manifold 222 is coupled to mounting structure 214 at one pair of brackets 220 such that manifold 222 extends downwardly from base 216 as shown in, e.g., FIG. 2. More particularly, manifold body 228 extends along the length L of base 216 between a pair of brackets 220, such that manifold body is parallel to the length L of base 216. As described above, manifold 222 may include corresponding features, not shown in FIGS. 2-8, to allow engagement with detent features 264 on brackets 220.

Manifold body 228 includes a plurality of fluid outlets 226. As shown particularly in FIGS. 3-4 and 6, fluid outlets 226 are formed as openings within manifold body 228, with fluid outlets 226 oriented to direct fluid such as a liquid coolant outward from manifold body 228. In some examples, engagement of the manifold 222 with clocking features 264 orients the fluid outlets 226. The fluid outlets 226 may be oriented to direct fluid over particular electronic components.

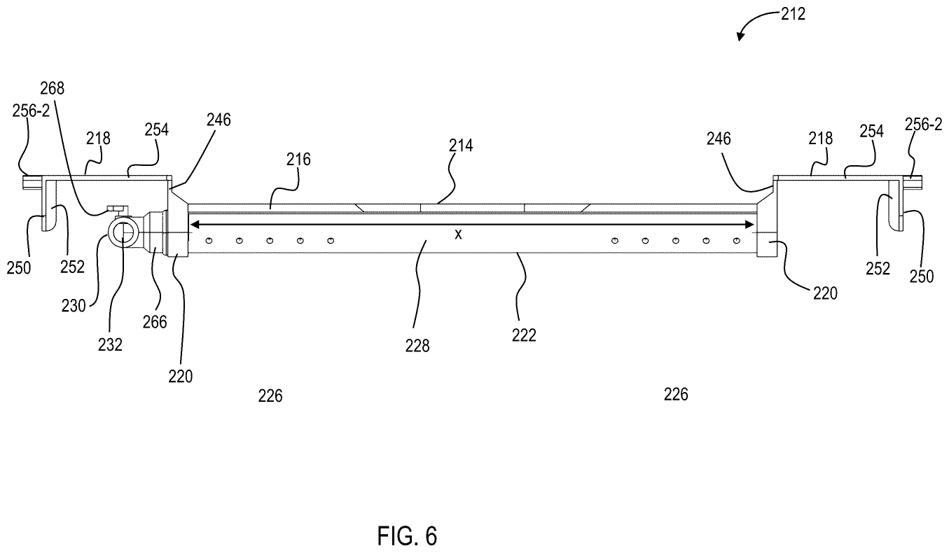

The direction of fluid flow from fluid outlets 226 is shown in FIGS. 3-4 by dotted line arrows extending from the fluid outlets 226. While ten fluid outlets 226 are shown in FIGS. 2-4 and 6, examples are not so limited, and more or fewer fluid outlets 226 may be used. In addition, as shown particularly in FIG. 6, fluid outlets 226 are disposed linearly along an x-axis of the manifold body 228, with the fluid outlets 226 disposed closer to the ends of the manifold body 228. However, fluid outlets 226 may be disposed elsewhere on the manifold body 228 and in other orientations with respect to the x-axis of manifold body 228. In addition, fluid outlets 226 may be extended along more of the length of manifold body 228 than is shown in FIGS. 3-4 and 6.

Manifold 220 further includes a pair of fluid inlets 224. Fluid inlets 224 are separated by manifold body 228. At least one fluid inlet 224 may be fluidically coupled to a distribution pipe 230 by a fluid coupling 266. More particularly, fluid inlet 224 is fluidically coupled to an outlet 236 of distribution pipe 230.

Distribution pipe 230 includes a pair of inlets 232 separated by a distribution pipe body 234. Inlets 232 are disposed at opposite ends of distribution pipe body 234, such that fluid, such as a liquid coolant, is able to enter distribution pipe 230 at either end and flow through distribution pipe body 234. A pair of outlets 236 are disposed in distribution pipe body 234, such that outlets 236 are fluidically coupled with inlets 232 via distribution pipe body 234.

Distribution pipe 230 is coupled to mounting structure 214 by engagement of a fluid coupling 266 with a bracket 220. More particularly, a fluid coupling 266 is engaged with a bracket 220 at the opening 262 by, for example, engagement of screw threading or a friction fit between the bracket 220 and the fluid coupling 266. The fluid coupling 266 then engages with an outlet 236, such that outlets 236 of distribution pipe 230 are coupled to mounting structure 214. As such, distribution pipe 230 is movable and thus can be coupled to mounting structure 214 at either side of base 216. The particular side of the mounting structure 214 to which the distribution pipe 230 is coupled may be determined by system considerations, including system board orientation and location of electrical components to be cooled.

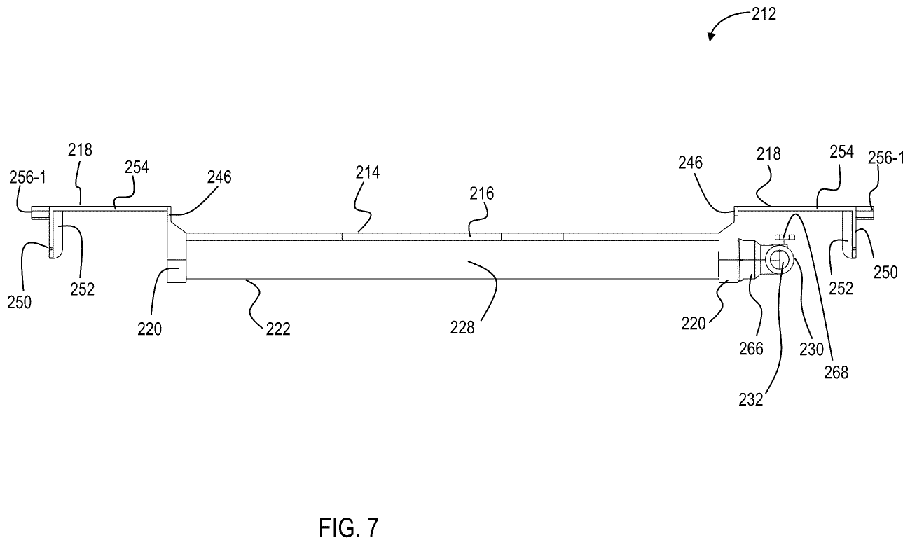

As shown in FIGS. 3 and 7, in particular, one fluid coupling 266 is coupled to a bracket 220 to which manifold 222 is also coupled. In this manner, a fluid inlet 224 is fluidically coupled with distribution pipe 230, and more particularly with an outlet 236 of distribution pipe 234. This allows fluid to enter inlet 232 of distribution pipe 230, as shown in FIG. 4, depicted by the dotted line arrow labeled A. Fluid flows through the distribution pipe body 234 and out through outlet 236. Due to the fluidic coupling of outlet 236 of distribution pipe 230 and fluid inlet 224 of manifold 222, fluid then flows into manifold 222 at fluid inlet 224. The fluid then flows out of manifold body 228 at fluid outlets 226. The outward flow of fluid at fluid outlets 226 is indicated by the dotted line arrows extending from fluid outlets 226. In this manner, fluid is moved through modular manifold assembly 212 when the modular manifold assembly 212 is installed in a system that is immersed in a cooling liquid.

Distribution pipe 230 further includes one or more valves 268. As used herein, a valve refers to a device configured to control the passage of a fluid through an opening, such as a pipe or duct. In some examples, valve 268 is a bidirectional valve, which is able to control passage of a fluid in two directions. In some examples, valve 268 is movable between two positions to selectively connect or disconnect one inlet 232 from the remainder of the distribution pipe 230 (in some examples) or from the adjacent outlet 236 (in some examples). This can allow, for example, one inlet 232 to be open for fluid to enter distribution pipe 230 while the other inlet 232 is closed, or it can allow for both inlets 232 to be opened to input liquid to the distribution pipe 230. In other examples, valve 268 is a three-way valve configured to selectively close or open connections between a corresponding inlet 232 a corresponding outlet 236, and the remainder of the distribution pipe 230. In such a configuration, the valve 268 can have the following positions: a first position in which it allows liquid to flow from the corresponding inlet 232 to both the corresponding outlet 236 and the distribution pipe 230 (from whence the liquid may eventually reach other outlets 236); a second position in which it allows liquid to flow from the corresponding inlet 232 to the corresponding outlet 236 but blocks liquid flow to the remainder of the pipe 230; a third position in which it allows liquid to flow from the remainder of the pipe 230 (e.g., from a distant inlet 232) to the corresponding outlet 236, but blocks liquid flowing to or from the corresponding inlet 232; and a fourth position in which it blocks all liquid from flowing through the valve 268. In either of the bidirectional or three-way examples, valve(s) 268 allow(s) distribution pipe 230 to be selectively configured to direct the flows of liquid to the manifold 222 regardless of which set of brackets 220 the manifold 222 is coupled to and to accept liquid input through either, or both, of the inlets 232. This flexibility can allow the manifold assembly 212 to be reconfigured as may be desired to meet the different conditions that may be encountered in different systems. For example, in one system, a bulk flow direction of liquid may be front-to-rear, in which case it may be desired to position the manifold 222 in a forwardmost pair of the brackets 220 so that the output streams flow in a generally rearward direction, aligned with the bulk flow direction, but in another system which has a bulk flow direction of liquid from rear-to-front, it may be desired to mount the manifold 220 to the rearmost pair of brackets 220. The valves 268 can enable the same manifold assembly 212 to be configurable for use in both systems, thus avoiding the cost of having to design and produce different manifold assemblies for different systems. As another example, in one system the pump that supplies liquid to the manifold assembly 212 may be disposed in a front portion of a chassis, making it convenient to connect the pump to the forwardmost inlet 232, but in another system the pump may be located in a rear portion of the chassis, making it more convenient to connect to the rearmost inlet 232. The valves 268 allow whichever inlet 232 is most convenient to be used in the given system, which can avoid the need for designing separate manifold assemblies 212 for each system.

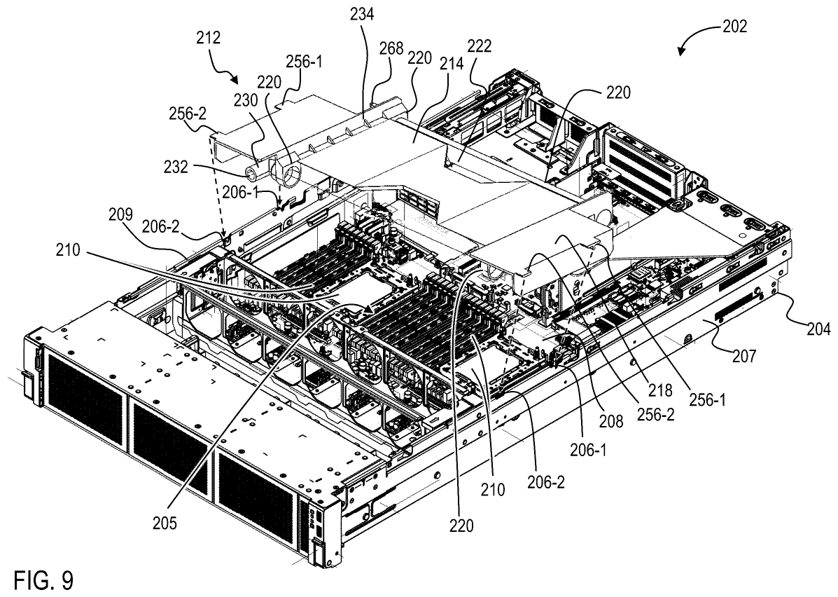

FIG. 9 is a perspective view of an information processing system 202 in which the modular manifold assembly 212 described above may be used. Information processing system 202 is one example implementation of information processing system 102 described above. Components of system 202 which correspond to (e.g., are implementation examples of) components of system 102 are given similar reference numbers, such as 104 and 204.

Information processing system 202 includes a chassis 204 supporting a system board 208, as well as the modular manifold assembly 212 described above. In this example, information processing system 202 is a rack-mountable server having capability of an air-cooled configuration and an immersion cooled configuration, with the system 202 being depicted in a process of being configured into the immersion cooled configuration by, among other things, the installation of modular manifold assembly 212 in chassis 204.

System board 208 includes a plurality of electronic components 210. While two electronic components 210 are shown in FIG. 9, examples are not so limited and more or fewer electronic components 210 may be present. In this example, electronic components 210 include two CPU sockets, as well as one or more CPUs (not illustrated) mounted to those CPU sockets in a fully assembled state of the system 202. The electronic components 210 also include, in this example, multiple memory module slots, as well as one or more memory modules (not illustrated) installed in those slots in a fully assembled state of the system 202. The system 202 also includes other information processing components.

Chassis 204 includes a fan shroud region 205 and a plurality of fan shroud attachment points 206 formed as part of the chassis 204. In this example, fan shroud region 205 comprises the space above the electronic components 210 (e.g., the space above the CPUs and memory modules). In other words, the fan shroud region 205 may be bounded below by the CPUs and memory modules, above by a cover (not illustrated) of chassis 204, and laterally by the side walls 207 and 209 of chassis 204. As shown in FIG. 9, in this example, fan shroud attachment points 206 may be disposed on side walls 207 and 209 of chassis 204, although other examples are not so limited. Fan shroud attachment points 206 may be configured to mate with a fan shroud (not present in FIG. 9) to help direct air in an air-cooled configuration of the system 202. However, as shown in FIG. 9, in the immersion cooled configuration, a fan shroud is not present, allowing modular manifold assembly 212 to be installed in information processing system 202 such that modular manifold assembly 212 occupies fan shroud region 205. It should be understood that, while FIG. 9 does not show modular manifold assembly 212 in an installed position, modular manifold assembly 212 is configured to engage with the chassis 204 at the fan shroud attachment points 206 and that, in the engaged state, modular adapter is disposed above system board 208 and electronic components 210.

More particularly, modular manifold assembly 212 includes a mounting structure 214, that includes attachment features 256-1, 256-2 (collectively attachment features 256) as already described above. Attachment features 256 are configured to engage with the fan shroud attachment points 206 on chassis 204, as indicated by the dashed line arrows extending between each attachment feature 256 and a corresponding fan shroud attachment point 206, allowing modular manifold assembly 212 to be installed within information processing system 202. More specifically, in this example, attachment points 256 include two types of attachment points, namely attachment points 256-1 configured to engage attachment features 256-1 and attachment points 256-2 configured to engage attachment points 256-2. The attachment points 256-1 comprise a T-shaped opening formed in a top edge of side wall 207 or 209 of chassis 204 which includes a horizontal slot and a vertical slot joined perpendicularly. A bottom edge of the horizontal slot forms a shelf upon which a horizontal portion of attachment point 256-1 can rest, while a vertical portion of attachment point 256-1 sits within the vertical slot. The attachment points 256-2 comprise a horizontal slot opening formed in a top edge of side wall 207 or 209 of chassis 204, with a bottom edge of the horizontal slot forming a shelf upon which the tab of attachment point 256-2 can rest. Both the attachment points 256-1 and 256-2 are recessed relative to a top edge of the side walls 207/209 sufficiently to allow modular manifold assembly 212 to sit down in the chassis 204 without protruding above the top edge of the side walls 207/209, thus avoiding interference between the modular manifold assembly 212 and a top cover (not illustrated).

A manifold 222 is coupled to mounting structure 214 at brackets 220 such that, in an installed position of modular manifold assembly 212 at chassis 204, fluid outlets (not shown in FIG. 9) in the manifold 222 are disposed such that the fluid outlets face electronic components 210. A distribution pipe 230 is coupled to mounting structure 214 at brackets 230, and manifold 222 is fluidically coupled to an outlet of distribution pipe 230. The distribution pipe 230 includes inlets 232, one of which is shown in FIG. 9. Distribution pipe 230 further includes a bidirectional valve 268 to allow selection of a direction of fluid flow through distribution pipe 230.

When information processing system 202 is immersed in an immersion tank having a pool of liquid coolant, such as immersion tank 138 having liquid coolant 140, described with respect to FIG. 1, liquid coolant is moved through an input 232 of distribution pipe 230, where it is then moved through the manifold 222 and directed over electronic components 210 via the fluid outlets. More specifically, system 202 may further include a pump (not illustrated) and liquid conduits which connect the pump to the inlet(s) 232 of distribution pipe, such that the pump can draw in liquid coolant from the pool and force it to flow through the distribution pipe 230 and manifold 222. Thus, even when information processing system 202 is immersed in the liquid coolant to provide system cooling, certain electronic components are able to receive additional cooling, allowing information processing system 202 to remain at an operating temperature that is unlikely to cause heat-related damage to the system components.

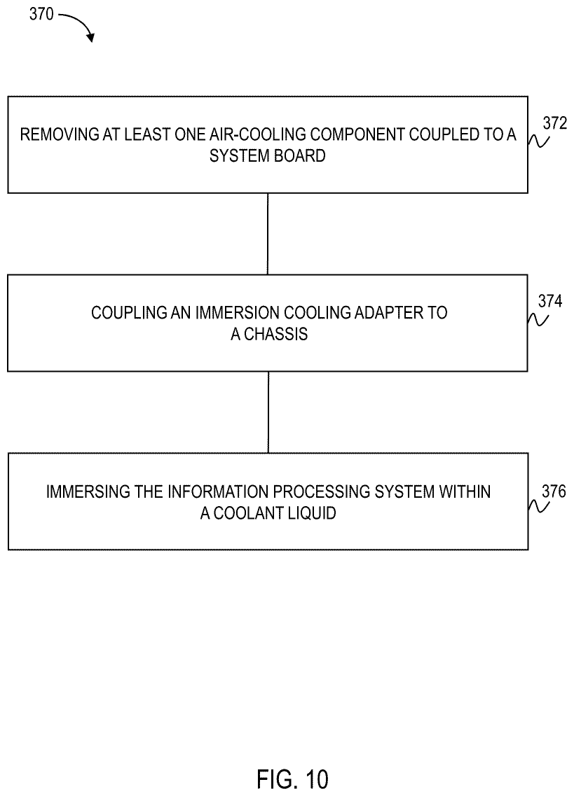

FIG. 10 is a method 370 for adapting a system to include a modular manifold assembly. At 372, method 370 includes removing at least one air-cooling component coupled to a system board. The air-cooling component may be a fan shroud, a fan, or any other component used in an air-cooled system. Removal of the at least one air-cooling component creates an available volume on the system board. That is, by removing at least one air-cooled component, the system board has an empty space which used to be occupied by the at least one air-cooled component.

At 374, method 370 includes coupling an modular manifold assembly to a chassis. The modular manifold assembly may include a mounting structure and a manifold. More particularly, coupling a modular manifold assembly to a chassis may include coupling the manifold to the mounting structure. The mounting structure may include a base and a pair of side arms. Coupling the manifold to the mounting structure may further comprise coupling the manifold to the base of the mounting structure at a plurality of brackets on the base, with the manifold being configured to be received within the brackets. An inlet of the manifold may then be coupled to a distribution pipe coupled to the base. More particularly, the inlet of the manifold may be fluidically coupled to an output of the distribution pipe.

Coupling the modular manifold assembly to the chassis may further comprise coupling the mounting structure to the chassis. The pair of side arms may include a plurality of engagement features, and the engagement features on the side arms may be coupled to corresponding engagement features on the chassis. This attachment feature on the chassis may correspond to an engagement feature of the air-cooling component removed at 372. For example, as described with respect to FIGS. 1 and 9 in particular, the engagement features on the chassis may be fan shroud attachment points, although examples are not so limited. When the modular manifold assembly is coupled to the chassis, the modular manifold assembly is disposed within the available volume on the system board. Said differently, modular manifold assembly is configured to occupy the space originally occupied by the at least one air-cooling component, which was removed at 372.

At 376, method 370 includes immersing the information processing system within a coolant liquid. More particularly, immersing the information processing system within a coolant liquid at 376 comprises immersing at least a portion of the system board including the modular manifold assembly within the coolant liquid. This immersion allows coolant liquid to be moved to the manifold, providing cooling for components on the system board. In some examples, the coolant liquid is a dielectric liquid, although examples are not so limited.

It is to be understood that both the general description and the detailed description provide example implementations that are explanatory in nature and are intended to provide an understanding of the present disclosure without limiting the scope of the present disclosure. Other examples in accordance with the present disclosure will be apparent to those skilled in the art based on consideration of the disclosure herein. For example, various mechanical, compositional, structural, electronic, and operational changes may be made to the disclosed examples without departing from the scope of this disclosure, including for example the addition, removal, alteration, substitution, or rearrangement of elements of the disclosed examples, as would be apparent to one skilled in the art in consideration of the present disclosure. Moreover, it will be apparent to those skilled in the art that certain features or aspects of the present teachings may be utilized independently (even if they are disclosed together in some examples) or may be utilized together (even if disclosed in separate examples), whenever practical. In some instances, well-known circuits, structures, and techniques have not been shown or described in detail in order not to obscure the examples. Thus, the following claims are intended to be given their fullest breadth, including equivalents, under the applicable law, without being limited to the examples disclosed herein.

References herein to examples, implementations, or other similar references should be understood as referring to prophetic or hypothetical examples, rather than to devices/systems that have been actually produced, unless explicitly indicated otherwise. Similarly, references to qualities or characteristics of examples should be understood as representing the educated estimates or expectations of the inventors based on their understanding of the relevant principles involved, application of theory and/or modeling, and/or past experiences, rather than as being representations of the actual qualities or characteristics of an actually produced device/system or the empirical results of tests actually carried out, unless explicitly indicated otherwise.

Further, spatial, positional, and relational terminology used herein is chosen to aid the reader in understanding examples of the invention but is not intended to limit the invention to a particular reference frame, orientation, or positional relationship. For example, spatial, positional, and relational terms such as “up”, “down”, “lateral”, “beneath”, “below”, “lower”, “above”, “upper”, “proximal”, “distal”, and the like may be used herein to describe directions or to describe one element's or feature's spatial relationship to another element or feature as illustrated in the figures. These spatial terms are used relative to reference frames in the figures and are not limited to a particular reference frame in the real world. Furthermore, if a different reference frame is considered than the one illustrated in the figures, then the spatial terms used herein may need to be interpreted differently in that different reference frame. Moreover, the poses of items illustrated in the figure are chosen for convenience of illustration and description, but in an implementation in practice the items may be posed differently.

In addition, the singular forms “a”, “an”, and “the” are intended to include the plural forms as well, unless the context indicates otherwise. Moreover, the terms “comprises”, “comprising”, “includes”, and the like specify the presence of stated features, steps, operations, elements, and/or components but do not preclude the presence or addition of one or more other features, steps, operations, elements, components, and/or groups. Components described as coupled may be electronically or mechanically directly coupled, or they may be indirectly coupled via one or more intermediate components, unless specifically noted otherwise.

And/or: Occasionally the phrase “and/or” is used herein in conjunction with a list of items. This phrase means that any combination of items in the list—from a single item to all of the items and any permutation in between—may be included. Thus, for example, “A, B, and/or C” means “one of {A}, {B}, {C}, {A, B}, {A, C}, {C, B}, and {A, C, B}”.

Mathematical and geometric terms are not necessarily intended to be used in accordance with their strict definitions unless the context of the description indicates otherwise, because a person having ordinary skill in the art would understand that, for example, a substantially similar element that functions in a substantially similar way could easily fall within the scope of a descriptive term even though the term also has a strict definition. Moreover, unless otherwise noted herein or implied by the context, when terms of approximation such as “substantially,” “approximately,” “about,” “around,” “roughly,” and the like, are used, this should be understood as meaning that mathematical exactitude is not required and that instead a range of variation is being referred to that includes but is not strictly limited to the stated value, property, or relationship. In particular, in addition to any ranges explicitly stated herein (if any), the range of variation implied by the usage of such a term of approximation includes at least any inconsequential variations and also those variations that are typical in the relevant art for the type of item in question due to manufacturing or other tolerances. In any case, the range of variation may include at least values that are within ±1% of the stated value, property, or relationship unless indicated otherwise.

What is claimed is:

1. An information processing system, comprising:
a system board comprising electronic components;
a chassis supporting the system board and comprising fan shroud attachment points configured to receive a fan shroud; and
a modular manifold assembly having:
a mounting structure, the mounting structure comprising:
a base;
a side arm configured to couple to the chassis at the fan shroud attachment points; and
a plurality of brackets coupled to the base; and
at least one manifold configured to removably engage with the plurality of brackets;
wherein the at least one manifold is configured to, in a mounted state of the modular manifold assembly to the chassis and an immersed state of the information processing system in a pool of liquid coolant in an immersion cooling tank, receive a flow of the liquid coolant drawn from the pool and expel the flow back into the pool as a plurality of output streams, with the output streams being directed towards the electronic components.

2. The information processing system of claim 1, wherein:
a distribution pipe is coupled to the mounting structure at a subset of the plurality of brackets; and
the at least one manifold is fluidically coupled to the distribution pipe.

3. The information processing system of claim 2, wherein:
the distribution pipe comprises a pair of inlets located at opposing end portions of the distribution pipe and separated by a distribution pipe body; and
the distribution pipe comprises a plurality of outlets formed in the distribution pipe body, each outlet of the plurality of outlets coupled to a single bracket of the plurality of brackets.

4. The information processing system of claim 3, wherein the distribution pipe further comprises one or more valves to selectively close or open an inlet of the pair of inlets.

5. The information processing system of claim 3, wherein the distribution pipe further comprises one or more valves to selectively close or open an outlet of the plurality of outlets.

6. The information processing system of claim 3, wherein the distribution pipe further comprises one or more three-way valves, each configured to selectively close or open both an inlet of the pair of inlets and an outlet of the plurality of outlets.

7. The information processing system of claim 1, wherein the modular manifold assembly is configured to be positioned in the chassis in a fan shroud region in lieu of a fan shroud, the fan shroud region comprising a space between one or more of the electronic components and a cover of the chassis.

8. The information processing system of claim 1, wherein the side arm further comprises:
a first vertical portion coupled to the base of the mounting structure and extending away from the base of the mounting structure:
a second vertical portion offset from and parallel to the first vertical portion; and
a top portion disposed between and connecting the first vertical portion and the second vertical portion, the top portion further comprising a plurality of engagement features to engage with the chassis at the fan shroud attachment points.

9. The information processing system of claim 1, wherein the plurality of brackets further comprises multiple pairs of brackets, each pair configured to hold one of the at least one manifold.

10. The information processing system of claim 1, wherein the at least one manifold further comprises:
a fluid inlet;
a manifold body coupled to the fluid inlet and defining a volume; and
a plurality of outlets in the manifold body and fluidically coupled to the fluid inlet, the plurality of outlets configured to output the one or more output streams.

11. The information processing system of claim 10, wherein the manifold is configured such that, on condition of the side arm being coupled to the chassis, the one or more output streams are directed to flow towards or over one or more of the electronic components.

12. The information processing system of claim 1, wherein:
the plurality of brackets further comprise at least one detent feature configured to engage with a corresponding detent feature on the at least one manifold in a state of the manifold installed in the plurality of brackets; and
the at least one detent feature is a locking mechanism to lock the at least one manifold in position with respect to the plurality of brackets.

13. A modular manifold assembly, comprising:
a mounting structure having a base and a pair of side arms, the side arms configured to couple to a chassis at attachment points on the chassis;
a manifold removably coupled to the base, the manifold further comprising a fluid inlet, a manifold body coupled to the fluid inlet, and a plurality of fluid outlets formed within the manifold body; and
a distribution pipe coupled to the base and fluidically coupled with the manifold at the fluid inlet of the manifold.

14. The modular manifold assembly of claim 13, wherein the manifold is configured to, in an immersed state of the modular manifold assembly in a pool of liquid coolant in an immersion cooling tank, receive via the fluid inlet a flow of the liquid coolant drawn from the pool and expel the flow back into the pool as a plurality of output streams via the plurality of fluid outlets.

15. The modular manifold assembly of claim 13, wherein the distribution pipe further comprises:
a first fluid inlet;
a second fluid inlet;
a distribution pipe body disposed between and connecting the first fluid inlet and the second fluid inlet;
at least one fluid outlet; and
an adjustable bidirectional valve configured to adjust a direction of flow of coolant liquid when the information processing system is immersed in the liquid coolant.

16. The modular manifold assembly of claim 15, wherein the at least one fluid outlet of the distribution pipe is fluidically coupled to the fluid inlet of the manifold.

17. The modular manifold assembly of claim 13, wherein the plurality of fluid outlets are oriented such that fluid passing through the plurality of fluid outlets is directed over at least one particular component of the plurality of information processing components.

18. The modular manifold assembly of claim 17, wherein the plurality of fluid outlets are oriented by engagement of a detent feature on the manifold body with a corresponding detent feature on at least one bracket of the base.

19. A method for adapting an information processing system for immersion cooling, comprising:
removing at least one air-cooling component coupled to a system board, wherein removing at least one air-cooling component creates an available volume;
coupling an immersion cooling adapter including a mounting structure and a manifold to a chassis, wherein the immersion cooling adapter is coupled to the chassis such that the immersion cooling adapter is disposed within the available volume; and
immersing the information processing system within a coolant liquid.

20. The method of claim 19, wherein coupling an immersion cooling adapter to the chassis further comprises:
coupling the manifold to the mounting structure, the mounting structure including a base and a pair of side arms having a plurality of engagement features, wherein coupling at the manifold to the mounting structure further comprises:
coupling the manifold to the base at a plurality of brackets on the base; and
coupling an inlet of the manifold to a distribution pipe coupled to the base, wherein the inlet of the manifold is fluidically coupled to an output of the distribution pipe; and
coupling the mounting structure to the chassis by engaging the plurality of engagement features with corresponding engagement features on the chassis.
